(19) United States
(12) Patent Application Publication
(10) Pub. No.: US 2024/0047529 A1
(43) Pub. Date: Feb. 8, 2024

(54) GAN DEVICES WITH MODIFIED HETEROJUNCTION STRUCTURE AND METHODS OF MAKING THEREOF

(71) Applicant: Texas Instruments Incorporated, Dallas, TX (US)

(72) Inventors: DONG SEUP LEE, MCKINNEY, TX (US); CHANG SOO SUH, ALLEN, TX (US); YOGANAND SARIPALLI, ALLEN, TX (US); MENG-CHIA LEE, ALLEN, TX (US); JUNGWOO JOH, ALLEN, TX (US); JAMES TEHERANI, PLANO, TX (US); SANDEEP BAHL, PALO ALTO, CA (US)

(21) Appl. No.: 17/823,777

(22) Filed: Aug. 31, 2022

Related U.S. Application Data
(60) Provisional application No. 63/370,739, filed on Aug. 8, 2022.

(51) Int. Cl. H01L 29/08; H01L 29/20; H01L 29/205; H01L 29/40; H01L 29/778; H01L 29/66

(52) U.S. Cl. CPC H01L 29/0891; H01L 29/2003; H01L 29/205; H01L 29/404; H01L 29/7786; H01L 29/66462

(57) ABSTRACT

GaN devices with a modified heterojunction structure and methods of making thereof are described. The GaN device comprises a heterojunction structure modified to include one or more deactivated regions. The heterojunction structure of the deactivated regions has different structural configurations than that of the as-grown heterojunction structure. The locally confined structural alteration of the heterojunction structure weakens or prohibits 2DEG formation in the deactivated regions. Moreover, the amount of net charges mapped to a field plate positioned above the heterojunction structure can be locally reduced or eliminated. Consequently, the electric field present between the heterojunction structure and the field plate can be reduced.

### CROSS-REFERENCE TO RELATED APPLICATIONS

The present Application for Patent claims the benefit of U.S. Provisional Patent Application No. 63/370,739, entitled “GaN Devices with Local 2-DEG Modification,” filed Aug. 8, 2022, which is hereby incorporated by reference in its entirety herein.

### TECHNICAL FIELD

The present disclosure generally relates to the field of semiconductor devices, and more particularly to GaN devices with modified heterojunction structure and methods of making thereof.

### BACKGROUND

Semiconductor devices based on gallium nitride (GaN-based semiconductor devices) can deliver various characteristics that are superior than silicon-based semiconductor devices. GaN-based semiconductor devices typically include a heterojunction structure that induces highly-mobile 2-dimensional electron gas (2DEG) at the interface of two dissimilar semiconductor materials. GaN-based semiconductor devices have faster switching speed than silicon-based semiconductor devices and excellent reverse-recovery performance. GaN-based semiconductor devices are suitable for low-loss and high-efficiency performance applications.

### SUMMARY

The present disclosure describes GaN-based semiconductor devices (GaN devices) with modified heterojunction structure and methods of making thereof. This summary is not an extensive overview of the disclosure, and is neither intended to identify key or critical elements of the disclosure, nor to delineate the scope thereof. Rather, the primary purpose of the summary is to present some concepts of the disclosure in a simplified form as a prelude to a more detailed description that is presented later.

In some embodiments, a transistor comprises a gallium nitride (GaN) heterojunction structure over a substrate, the GaN heterojunction structure including a GaN-based alloy layer formed on a GaN layer; a source contact structure, a drain contact structure, and a gate contact structure located between the source and drain contact structures, where the source, drain, and gate contact structures are supported by the GaN-based alloy layer; and a hybrid drain contact structure located alongside of the drain contact structure, where the hybrid drain contact structure is supported by the GaN-based alloy layer, and where the GaN heterojunction structure includes: a drain access area between the gate and drain contact structures, the drain access area having a first layer of electrons with a first electron concentration at a surface of the GaN layer facing the GaN-based alloy layer; and a deactivated region enclosed by the drain access area, the deactivated region having a second layer of electrons with a second electron concentration at the surface of the GaN layer facing the GaN-based alloy layer, where the second electron concentration is less than the first electron concentration.

In some embodiments, a method comprises forming a gallium nitride (GaN) heterojunction structure over a substrate, the GaN heterojunction structure including a GaN-based alloy layer formed on a GaN layer; forming a deactivated region of the GaN heterojunction structure; and forming a source contact structure, a drain contact structure, a gate contact structure located between the source and drain contact structures, and a hybrid drain contact structure located alongside of the drain contact structure, where the source, drain, gate, and hybrid drain contact structures are supported by the GaN-based alloy layer, and where the GaN heterojunction structure between the gate and drain contact structures corresponds to a drain access area including a first layer of electrons having a first electron concentration at a surface of the GaN layer facing the GaN-based alloy layer; and the deactivated region is enclosed by the drain access area, the deactivated region including a second layer of electrons having a second electron concentration at the surface of the GaN layer facing the GaN-based alloy layer, where the second electron concentration is less than the first electron concentration.

In some embodiments, a high electron mobility transistor (HEMT) comprises a gallium nitride (GaN) heterojunction structure over a substrate, the GaN heterojunction structure including a GaN-based alloy layer formed on a GaN layer; a source contact structure, a plurality of drain contact structures, and a gate contact structure located between the source contact structure and the plurality of drain contact structures, where the source, drain, and the gate contact structures are supported by the GaN-based alloy layer; and a plurality of hybrid drain contact structures supported by the GaN-based alloy layer, where individual drain contact structures alternate with individual hybrid drain contact structures, and where the GaN heterojunction structure includes: a drain access area between the gate and the plurality of drain contact structures, the drain access area including a first layer of electrons having a first electron concentration at a surface of the GaN layer facing the GaN-based alloy layer; and a plurality of deactivated regions with each of the deactivated regions enclosed by the drain access area and including a second layer of electrons having a second electron concentration at the surface of the GaN layer facing the GaN-based alloy layer, where the second electron concentration is less than the first electron concentration.

These and other aspects of the present disclosure may be understood with reference to the following detailed description.

### BRIEF DESCRIPTION OF THE DRAWINGS

FIG. 1 is a 3-dimensional schematic diagram of a GaN device in accordance with embodiments of the present disclosure;

FIGS. 2A through 2C are plan-view and cross-sectional schematic diagrams of a GaN device in accordance with embodiments of the present disclosure;

FIGS. 3A and 3B are cross-sectional schematic diagrams of GaN devices in accordance with embodiments of the present disclosure;

FIGS. 4A though 4C are cross-sectional schematic diagrams of GaN devices in accordance with embodiments of the present disclosure;

FIGS. 5A through 5L are plan-view and cross-sectional schematic diagrams illustrating process steps of generating a GaN device in accordance with embodiments of the present disclosure;

FIGS. 6A through 6D are plan-view schematic diagrams of GaN devices in accordance with embodiments of the present disclosure; and

FIG. 7 is a flowchart illustrating methods of generating GaN devices in accordance with aspects of the present disclosure.

### DETAILED DESCRIPTION

The present disclosure is described with reference to the attached figures. The components in the figures are not drawn to scale. Instead, emphasis is placed on clearly illustrating overall features and the principles of the present disclosure. Numerous specific details and relationships are set forth with reference to example embodiments of the figures to provide an understanding of the disclosure. It is to be understood that the figures and examples are not meant to limit the scope of the present disclosure to such example embodiments, and other embodiments are possible by way of interchanging or modifying at least some of the described or illustrated elements. Moreover, where elements of the present disclosure can be partially or fully implemented using known components, those portions of such components that facilitate an understanding of the present disclosure are described, and detailed descriptions of other portions of such components are omitted so as not to obscure the disclosure.

Various structures disclosed herein can be formed using semiconductor process techniques. Layers including a variety of materials can be formed over a substrate, for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps.

The semiconductor devices, integrated circuits, or IC components described herein may be formed on a semiconductor substrate (or die) including various semiconductor materials, such as silicon, germanium, silicon-germanium alloy, gallium arsenide, gallium nitride, silicon carbide, or the like. In some cases, the substrate refers to a semiconductor wafer. The conductivity (or resistivity) of the substrate (or regions of the substrate) can be controlled by doping techniques using various chemical species (which may also be referred to as dopant atoms) including, but not limited to, boron, indium, arsenic, or phosphorus—e.g., for a silicon substrate. Doping may be performed during the initial formation or growth of the substrate (or an epitaxial layer grown on the substrate), by ion-implantation, or other suitable doping techniques.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in the semiconductor devices in view of the orientation shown in the figures. For example, “upper” or “uppermost” can refer to a feature positioned closer to the top of a page than other features. It is to be understood that the terms so used are interchangeable under appropriate circumstances such that the embodiments of the technology described herein are, for example, capable of operation in other orientations than those illustrated or otherwise described herein.

GaN devices (e.g., GaN transistors) may be regarded as high electron mobility transistors (HEMTs) in view of a layer of highly-mobile electrons formed in the GaN devices, which may be referred to as 2-dimensional electron gas (2DEG). The 2DEG can be formed at an interface of a heterojunction structure having two dissimilar semiconductor materials in contact with each other. For example, a layer of a group-III nitride-based alloy material (e.g., aluminum gallium nitride (AlGaN)) can be formed (e.g., epitaxially grown) on another layer of a group-III nitride material (e.g., gallium nitride (GaN)) to form a heterojunction structure. Conduction-band offset between the two semiconductor materials and/or polarization discontinuity present in such a heterojunction structure can induce the 2DEG at its interface—e.g., at the surface of the GaN layer in contact with the AlGaN layer.

Without limitation by theory, the phenomenon of inducing/forming the 2DEG at the interface of the heterojunction structure may be modeled as (1) forming a sheet of fixed positive charges at the interface of the heterojunction structure, and (2) accumulating electrons at the interface to compensate the positive charges at the interface. Although some of the description herein focuses on heterojunction structures including a GaN-based alloy layer (e.g., AlGaN layer) and a GaN layer for illustration purpose, the present disclosure is not limited thereto. For example, the notion of having locally modified regions in the heterojunction structure and methods of locally modifying the heterojunction structure can be applied to other heterojunction structures that can induce the 2DEG at their interface.

GaN transistors include 2DEG formed between source and drain contact structures of the GaN transistors—e.g., 2DEG formed at the surface of a GaN layer in contact with an AlGaN layer, which provides a channel for current conduction between the source and drain contact structures. As such, the channel between the source and drain contact structures may be referred to as a surface channel or a device channel. Moreover, a gate contact structure is positioned between the source and drain contact structures to control the current conduction. The GaN transistors can be configured as enhancement-mode GaN transistors (e-mode GaN transistors) or depletion-mode GaN transistors (d-mode GaN transistors). The e-mode GaN transistors are configured to have electrons of the 2DEG depleted (absent) under the gate contact structure resulting in normally-OFF devices. The e-mode GaN transistors can be turned ON by applying a positive voltage to the gate contact structure. On the other hand, the d-mode GaN transistors are configured to have the 2DEG present under the gate contact structure resulting in normally-ON devices. The d-mode GaN transistors can be turned OFF by applying a negative voltage to the gate contact structure.

During high-voltage operations (e.g., switching operations turning the GaN transistors ON or OFF with a drain bias voltage being greater than 100V, 200V, 300V, or even greater), the electrons may get trapped at various sites located at or vicinity of the channel of the GaN transistors. The trapping sites may be present within a dielectric passivation layer (e.g., a silicon nitride layer) formed on the AlGaN layer, at the interface between the AlGaN layer and the dielectric passivation layer, at various crystallographic defect sites that may be present within the GaN layer, among others. The trapped electrons may reduce the electron concentration in the channel, which in turn may increase the resistance of the channel between the source and drain (e.g., dynamic R_{DS_ON}) when the GaN transistor is turned ON. In some cases, the dynamic R_{DS_ON} can increase approximately 50% or greater after certain high-voltage operations, resulting in dynamic R_{DS_ON} stability issues.

In some cases, the dynamic R_{DS_ON} stability issue can be mitigated by implementing hybrid drain structures. The hybrid drain structures can be formed next to (alongside of) the drain contact structures. In some embodiments, the hybrid drain structures are connected (tied) to the drain contact structures. The hybrid drain structures may include a p-type GaN layer (e.g., a GaN layer doped with magnesium) formed on the AlGaN layer. Without limitation by theory, the p-type GaN layer is expected to be forward biased under the high drain bias voltage such that holes can be injected under the hybrid drain structures. The holes are expected to migrate to the channel (and/or to the trapping sites), thereby negating (compensating) the trapped electrons and/or the adverse effect of the trapped electrons. As a result, the dynamic R_{DS_ON} increase may be reduced when the hybrid drain structures are implemented in the GaN transistors (e.g., e-mode GaN transistors). In some cases, the dynamic R_{DS_ON} increase after the high-voltage operations can be maintained approximately 30% or less, mitigating the dynamic R_{DS_ON} stability issues.

The hybrid drain structures, however, may degrade time-dependent dielectric breakdown (TDDB) lifetime of the GaN transistors. For example, certain GaN transistors with the hybrid drain structures are observed to develop failure sites (e.g., localized ruptures or destructions) in the dielectric layer above the heterojunction structure during the high-voltage stress conditions. The failure sites tend to be between an edge of a field plate of the GaN transistor and localized regions of the device channel, where the localized regions tend to align with the locations of the hybrid drain structures. Without limitation by theory, the holes injected by the hybrid drain structures during the high-voltage operating conditions may exacerbate local electric field between the field plate and the localized regions of the device channel. As a result, the TDDB lifetime of the GaN transistors may be degraded when the hybrid drain structures are implemented.

The present disclosure describes GaN devices (GaN transistors, HEMT transistors based on GaN) including a modified heterojunction structure. Such a GaN transistor includes an area of the heterojunction structure between its gate and drain contact structures, which may be referred to as a drain access area, modified (altered, changed) to include one or more deactivated regions. As described in more detail herein, the heterojunction structure of the deactivated regions include different structural configurations than the as-grown heterojunction structure. As a result of altering the structural configuration of the heterojunction structure, portions of the device channel corresponding to the deactivated regions may have a charge carrier concentration (e.g., electron concentration) that is less than that of the as-grown heterojunction structure. In this regard, the overall 2DEG distribution in the drain access area may be considered to have been modified as a result of forming the deactivated regions in the heterojunction structure. The deactivated regions are expected to reduce the risk of locally exacerbating the electric field between the field plate and the localized regions of the device channel where the dielectric failures are observed in the presence of the hybrid drain contact structures.

In some embodiments, the deactivated regions may be selectively implanted with foreign atoms (i.e., atoms or elements different than the constituent atoms of the heterojunction structure). The implanted atoms (and the implantation process conditions under which the atoms are implanted) are configured to alter (e.g., destroy, perturbate) the crystalline structure of the heterojunction structure (e.g., the wurtzite structure of the AlGaN/GaN layers) that induces 2DEG at the interface. As a result, the 2DEG formation may be locally reduced (or prohibited) in the device channel corresponding to the deactivated regions. In some embodiments, a thickness of the AlGaN layer may be locally reduced such that 2DEG formation is locally reduced (or prohibited if the GaN-based alloy layer is removed completely). In some embodiments, the heterojunction structure of the deactivated region may be locally replaced with a trench structure filled with one or more dielectric materials—e.g., analogous to forming mesa isolation structures.

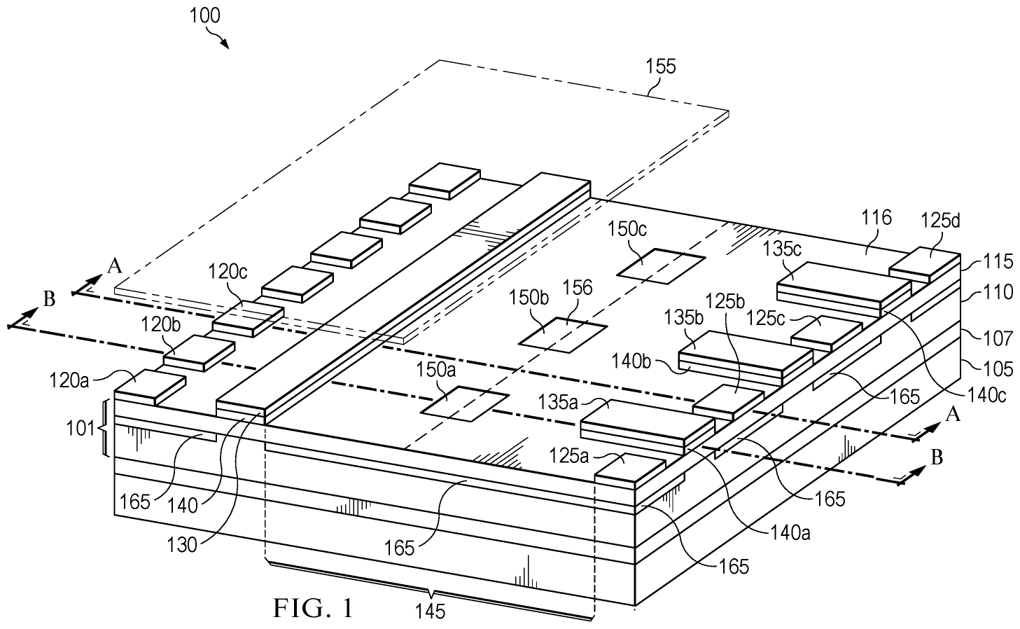

FIG. 1 is a 3-dimensional schematic diagram of a GaN device 100 (GaN transistor 100, HEMT 100) in accordance with embodiments of the present disclosure. The GaN transistor 100 is an e-mode GaN transistor and includes a heterojunction structure 101. The heterojunction structure 101 includes a GaN layer 110 and a GaN-based alloy layer 115 (e.g., AlGaN layer) formed on the GaN layer 110. The heterojunction structure 101 is formed over a substrate 105, which may include silicon, silicon carbide, sapphire, GaN-based substrate, or another suitable substrate material. A buffer layer 107 may be disposed on the substrate 105 to facilitate forming (e.g., epitaxially growing) the heterojunction structure 101, for example, by mitigating issues associated with lattice mismatching between the substrate 105 and the heterojunction structure 101.

The GaN layer 110 may be undoped with dopant atoms—e.g., having an intrinsic concentration of charge carrier (electrons and/or holes). In some embodiments, the GaN layer 110 can be doped with carbon, or some other suitable dopant atoms. In some embodiments, the GaN layer 110 can include a stack of an undoped GaN layer on a carbon-doped GaN layer.

The GaN-based alloy layer 115 can be formed (e.g., epitaxially grown) on the GaN layer 110. The GaN-based alloy layer 115 can have a general form of Al(x)In(y)Ga(1-x-y)N, where x and y represent composition of aluminum and indium, respectively. For example, the GaN-based alloy layer 115 may correspond to Al(0.3)Ga(0.7)N, Al(0.2)Ga(0.8)N, Al(0.2)In(0.1)Ga(0.7)N, or the like. In this regard, gallium, nitrogen, indium, and aluminum can be considered as constituent atoms (elements) of the GaN-based alloy layer 115 (or the GaN-based heterojunction structure 101). The GaN-based alloy layer 115 may be configured to have a greater bandgap (e.g., when compared to the GaN layer 110), and may be referred to as a barrier layer for the GaN layer 110. The GaN-based alloy layer 115 (or the heterojunction structure 101) has a top side 116 (top surface 116), on which various layers or structures are formed. In some embodiments, the thickness of GaN-based alloy layer 115 can be in the range of few nanometers (e.g., 5 nm) to a few hundred nanometers (e.g., 300 nm). In some embodiments, the thickness of GaN layer 110 can be in the range of few nanometers (e.g., 5 nm) to a few tens of micrometers (e.g., 50 μm). The term “approximately,” as used herein, may refer to ±5% to ±10% variations of the recited values in some cases. In other cases, the term “approximately” may refer to ±10% to ±20% variations of the recited values.

The GaN transistor 100 includes 2-dimensional electron gas (2DEG) 165 formed at the interface of the GaN layer 110 and the GaN-based alloy layer 115. In other words, the 2DEG 165 is formed at the surface of the GaN layer 110, which is in contact with the GaN-based alloy layer 115. The 2DEG 165 provides a channel for current conduction between source and drain contact structures 120 and 125 of the GaN transistor 100. As such, the channel between the source and drain contact structures 120 and 125 may be referred to as a surface channel (or a device channel).

As described above, the 2DEG 165 may be induced, based at least in part on the polarization discontinuity and the offset in the conduction bands between the GaN layer 110 and the GaN-based alloy layer 115. Although the description herein is based on a GaN transistor 100 including a heterojunction structure 101 comprising the GaN-based alloy layer 115 (e.g., AlGaN layer) on the GaN layer 110 that forms the 2DEG 165 at their interface, the present disclosure also applies to other HEMTs including a heterojunction structure comprising a first layer of group-III nitride and a second layer of a different group-III nitride (or a combination of group-III and group-V nitride), where the heterojunction structure is configured to induce 2DEG at the interface between the first and second layers. In the aforementioned description, the group-III and group-V refer to the elements of the third (III) and fifth (V) columns of the periodic table of elements.

The GaN transistor 100 includes source contact structures 120 (several of which are also identified individually as source contact structures 120a-c), drain contact structures 125 (several of which are also identified individually as drain contact structures 125a-c), and a gate contact structure 130 between the source and drain contact structures 120 and 125. The source contact structures 120, the drain contact structures 125, and the gate contact structure 130 are supported by the GaN-based alloy layer 115. The term “support” or “supported by” as used herein is intended to mean either an indirect or a direct support. Thus, when the source and drain contact structures 120 and 125 are supported by the GaN-based alloy layer 115, that support may be a direct support. When the gate contact structure 130 is supported by the GaN-based alloy layer 115, that support may be an indirect support through other layers (e.g., through a p-type GaN layer 140).

The source and drain contact structures 120 and 125 may form ohmic contacts with the GaN-based alloy layer 115, respectively. The ohmic contact is a low resistance junction that facilitates current conduction between the source contact structures 120 and the GaN-based alloy layer 115, as well as between the drain contact structures 125 and the GaN-based alloy layer 115. Although the source and drain contact structures 120 and 125 are not in direct contact with the 2DEG 165 as depicted in FIG. 1, the electrons can conduct through the GaN-based alloy layer 115 under the source and drain contact structures 120 and 125. In some embodiments, the GaN-based alloy layer 115 in contact with the source and drain contact structures 120 and 125 can be modified during the process flow—e.g., through annealing steps carried out subsequent to forming the source and drain contact structures 120 and 125 on the GaN-based alloy layer 115. In this manner, the GaN-based alloy layer 115 under the source and drain contact structures 120 and 125 may facilitate electrons to conduct through the GaN-based alloy layer 115 between the 2DEG 165 and the source and drain contact structures 120 and 125, respectively. In other embodiments, the source and drain contact structures 120 and 125 may extend through the GaN-based alloy layer 115 to land on the GaN layer 110 (and the 2DEG 165).

The GaN transistor 100, an e-mode GaN transistor, includes a p-doped GaN layer 140 (p-GaN layer 140) that is positioned on the top surface 116 of the heterojunction structure 101. In some embodiments, the p-GaN layer 140 is doped with (includes) magnesium. The gate contact structure 130 is positioned on the p-GaN layer 140. The p-GaN layer 140 enables the GaN transistor 100 to function in the enhancement mode as the presence of the p-GaN layer 140 added on top of the heterojunction structure 101 depletes the electrons at the surface of the GaN layer 110 under the p-GaN layer 140.

Without limitation by theory, the p-GaN layer 140 added to the heterojunction structure 101 establishes a built-in potential difference between the p-GaN layer 140 and the GaN-based alloy layer 115 without altering the structural configuration of the heterojunction structure 101, which in turn locally alters the energy band diagram of the heterojunction structure 101 such that the 2DEG 165 is depleted at the surface of the GaN layer 110. In this manner, the channel provided by the 2DEG 165 between the source and drain contact structures 120 and 125 becomes discontinuous under the p-GaN layer 140 due to the lack of charge carriers (e.g., electrons) under the p-GaN layer 140. As such, the GaN transistor 100 is considered normally OFF and thus requires a positive voltage applied at the gate contact structure 130 to turn it ON—e.g., forming a layer of electrons under the gate contact structure 130 to fill the gap in the 2DEG 165. The gate contact structure 130 may form an ohmic contact with the p-GaN layer 140.

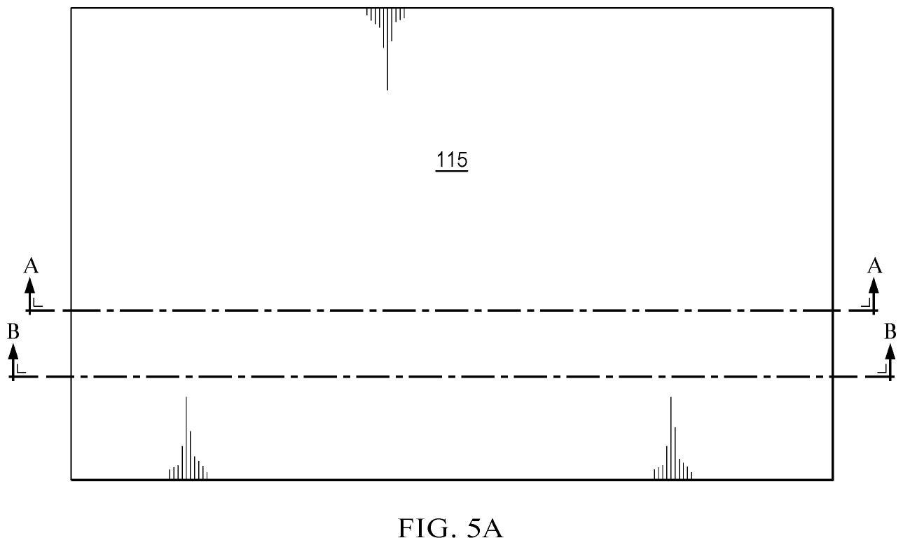

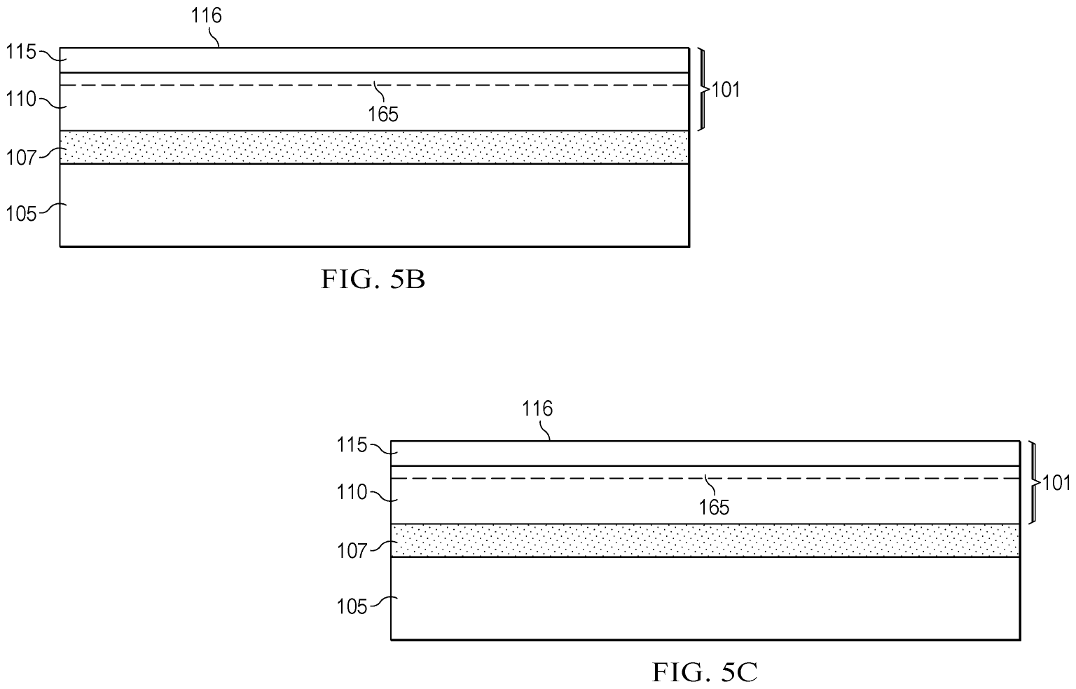

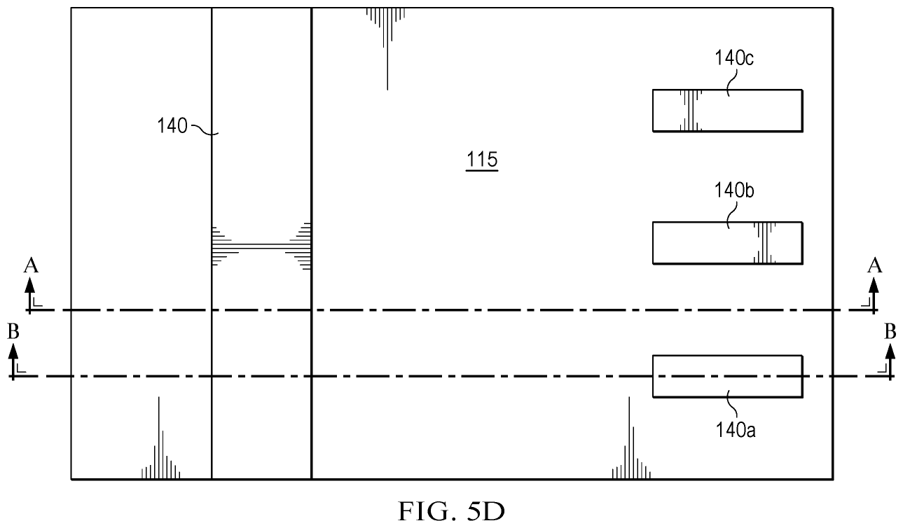

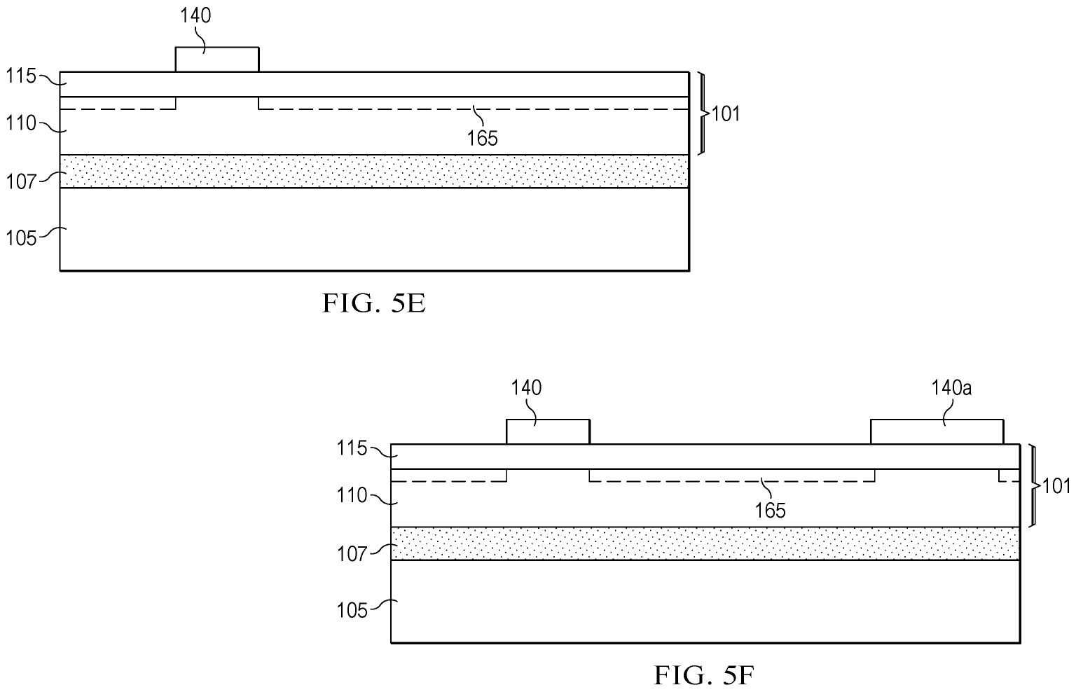

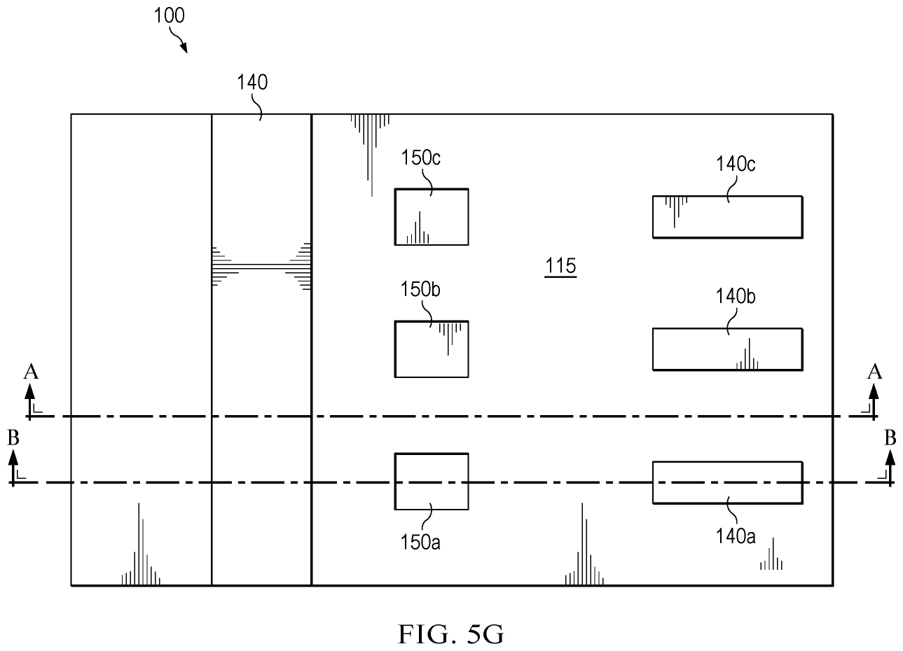

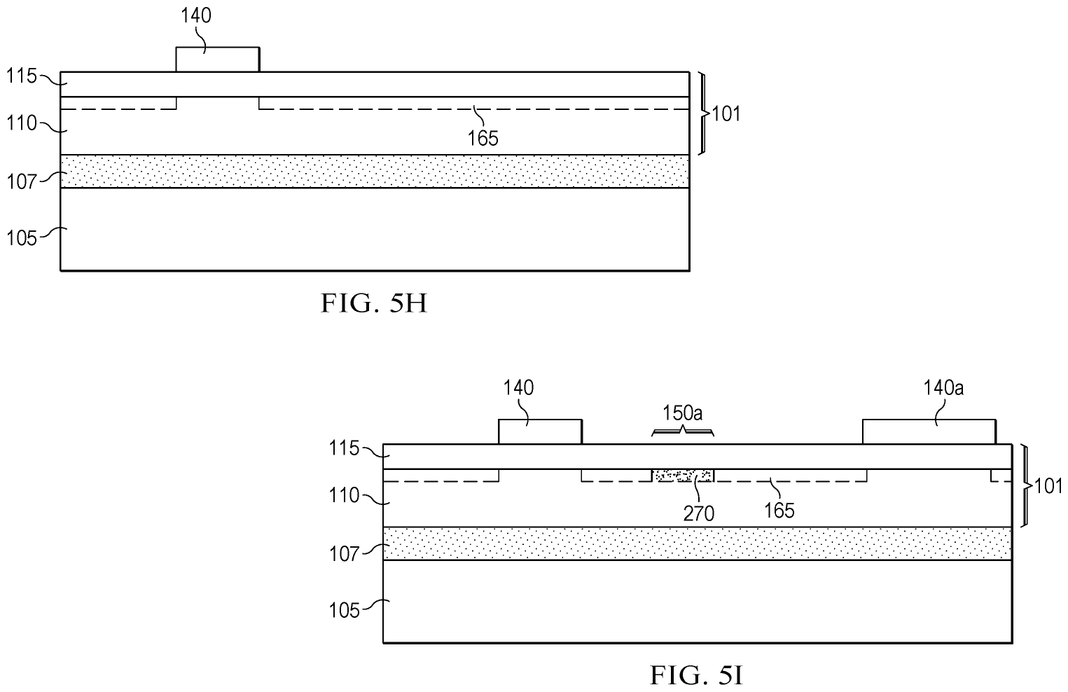

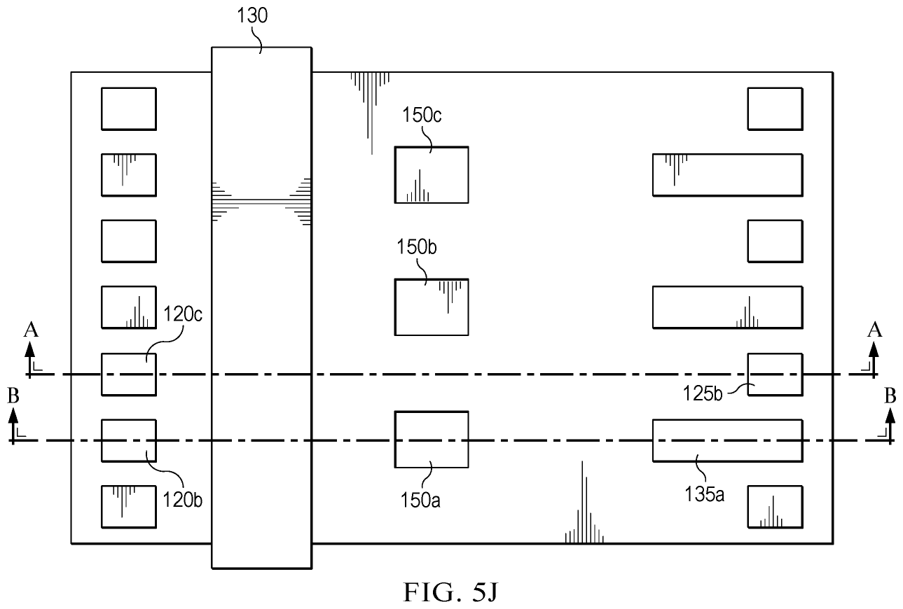

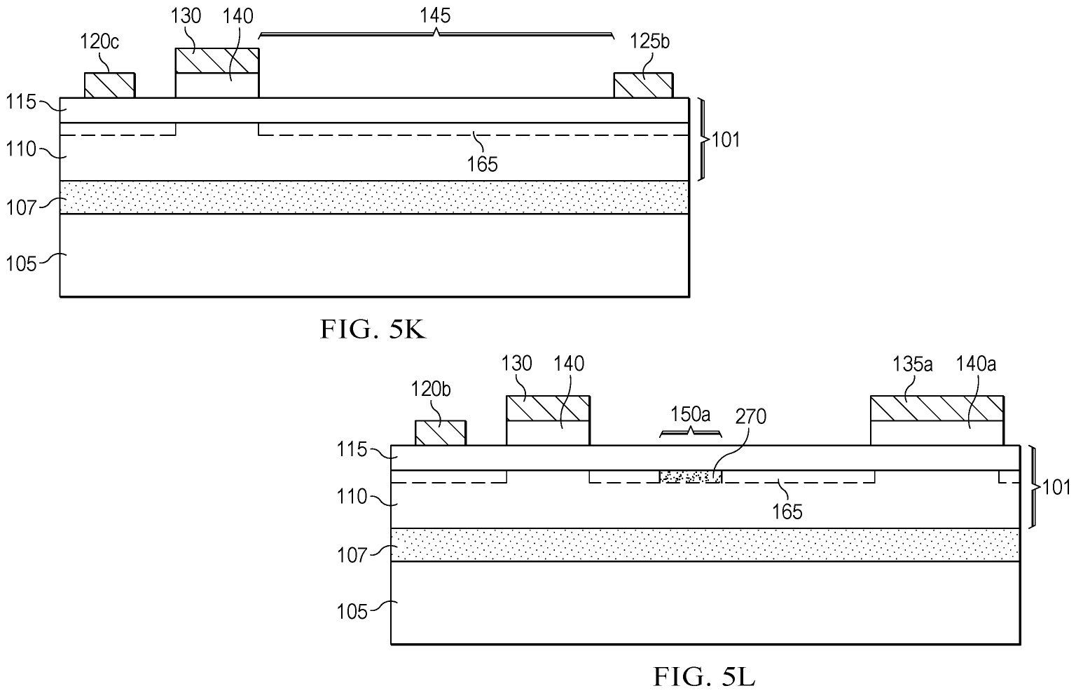

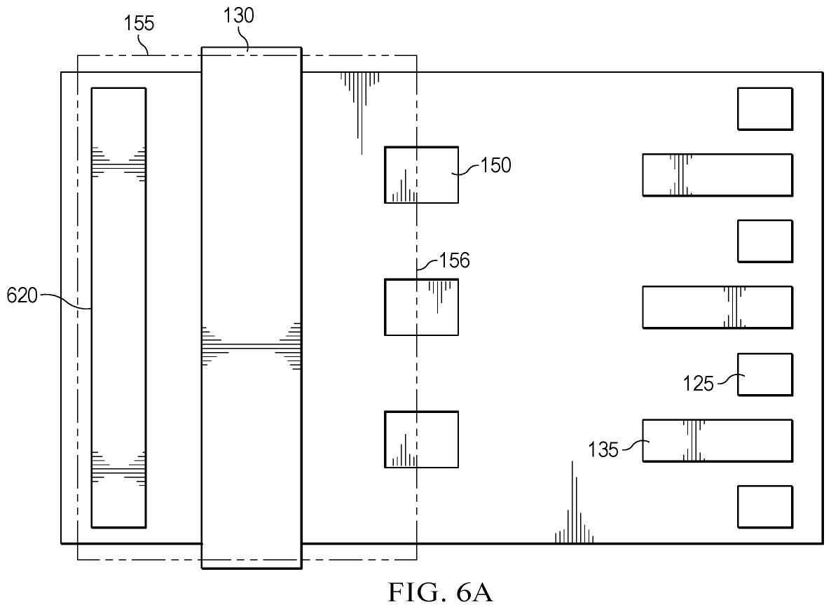

As described above, the GaN transistor 100 may experience charge trapping issues due to charge carriers (e.g., electrons) trapped at various trapping sites (e.g., within a passivation layer formed on the GaN-based alloy layer 115, at the interface between the passivation layer and the GaN-based alloy layer 115, at crystallographic defect sites in the GaN layer 110), which may be manifested as the dynamic R_{DS_ON} degradation. The GaN transistor 100 includes hybrid drain structures to mitigate the charge trapping issues, each of which includes the p-GaN layer 140 (also identified individually as p_GaN layers 140a-c) and a hybrid drain contact structure 135 (also identified individually as hybrid drain contact structures 135a-c). The p-GaN layer 140 under the gate contact structure 130 and the p-GaN layers 140a-c under the hybrid drain contact structure 135 can be formed (e.g., epitaxially grown) at the same time as described in more details herein with reference to FIGS. 5D-5F. As described with respect to the p-GaN layer 140 under the gate contact structure 130, the 2DEG 165 may be depleted under the p-GaN layers 140a-c.

The hybrid drain contact structures 135 may be connected to the drain contact structures 125. During the operation of the GaN transistor 100 (e.g., when the drain contact structures 125 (and the hybrid drain contact structures 135 connected thereto) are biased to a high drain bias voltage, e.g., 300V or even greater, the p-GaN layers 140a-c may inject holes (which can be regarded as positively charged particles) into the heterojunction structure 101 to compensate (e.g., negate, nullify) the trapped electrons at or near the channel such that the electron trapping issues (e.g., dynamic R_{DS_ON} stability issue) can be mitigated.

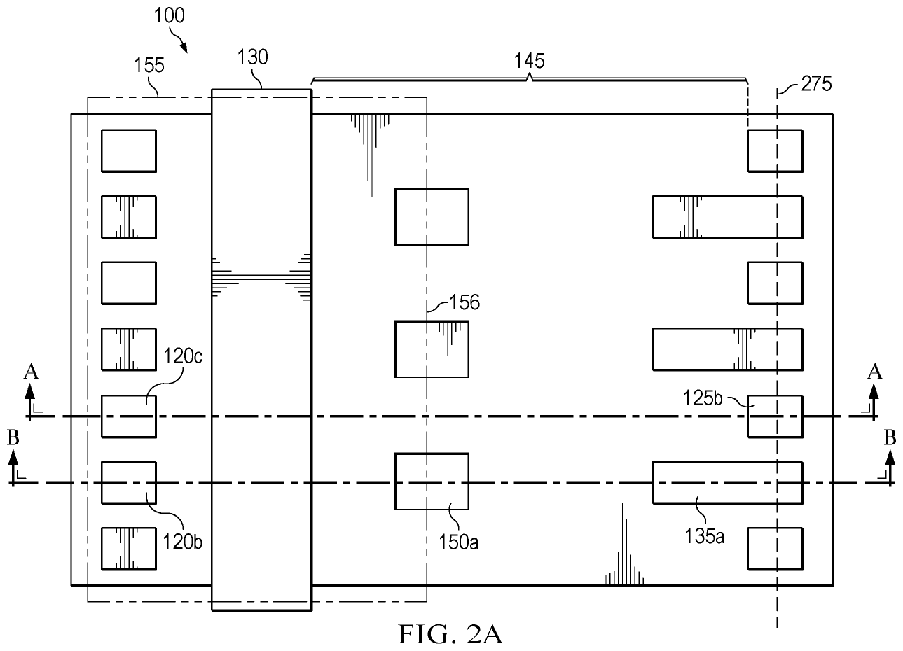

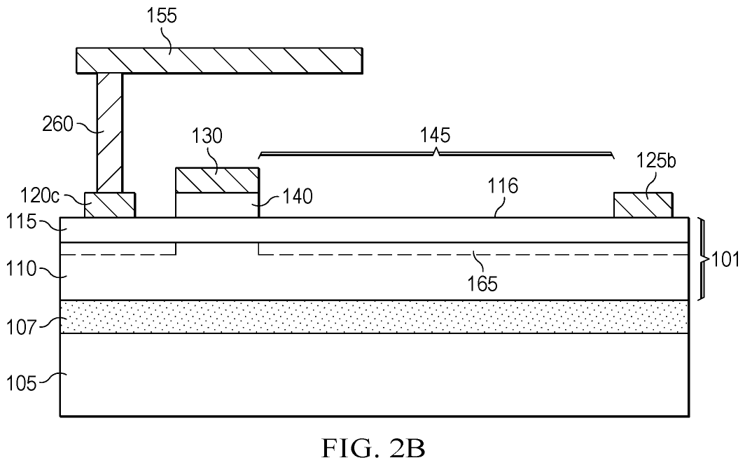

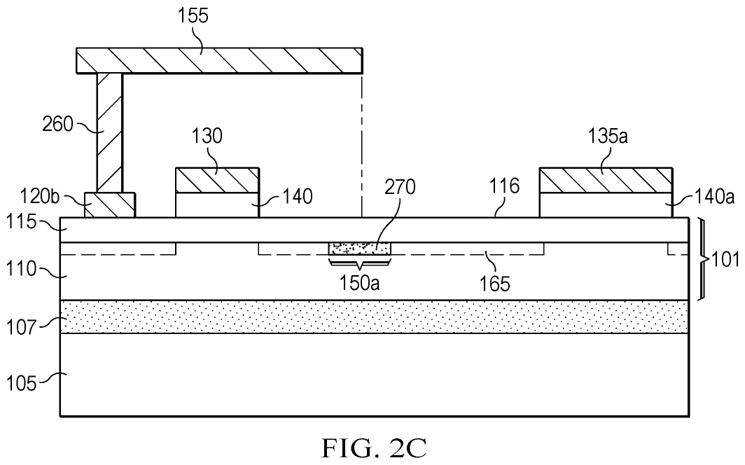

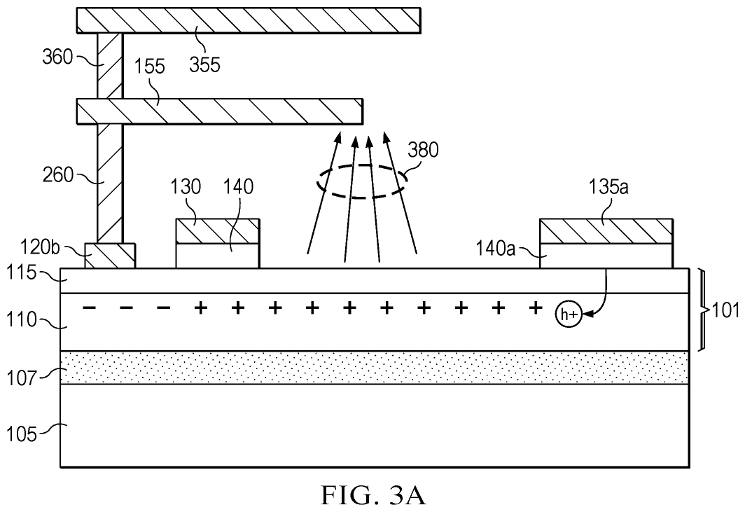

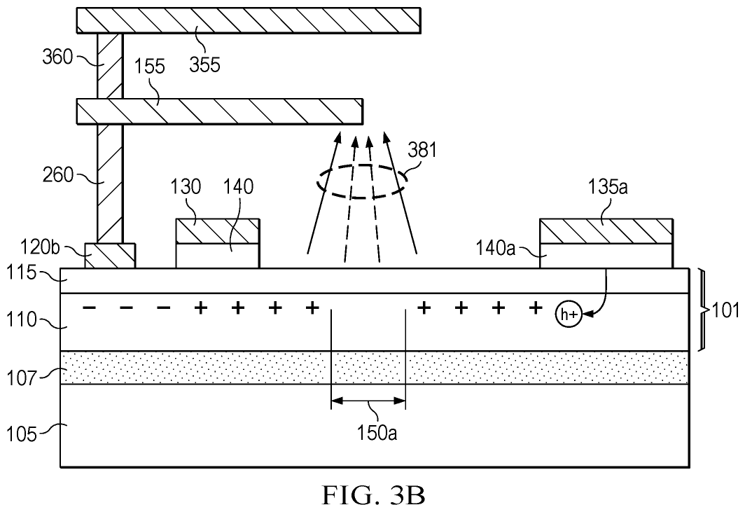

The heterojunction structure 101 includes an area between the gate and drain contact structures 130 and 125, which may be referred to as a drain access area 145. In other words, the drain access area 145 is the drain side of the heterojunction structure 101, which may be regarded as partitioned into two by the gate contact structure 130. The GaN transistor 100 also includes a field plate 155 formed over the source contact structures 120 and the gate contact structure 130. The field plate 155 is positioned such that an edge 156 of a footprint of the field plate 155 intersects the drain access area 145. In some embodiments, the field plate 155 is formed using a conductive layer available earliest in the process flow forming various interconnect structures subsequent to forming the source, drain, gate, and hybrid drain contact structures 120, 125, 130, and 135. Such interconnect structures may include local interconnect layers, multi-level metal layers, and contact/via structures, which are separated by multiple layers of dielectric materials. In some embodiments, the field plate 155 may be formed with a first metal (MT1) layer. The field plate 155 may be connected to the source contact structures 120 (e.g., as depicted in FIGS. 2B and 2C). As described in more details with reference to FIGS. 3A and 3B, the field plate 155 can be configured to bifurcate (spread, divide) the electric field present between the drain access area 145 and certain conductive structures above or near the drain access area 145.

The GaN transistor 100 also includes deactivated regions 150 (also identified individually as deactivated regions 150a-c) between the gate contact structure 130 and the hybrid drain contact structures 135. As depicted in FIG. 1, the deactivated regions 150 are enclosed by (surrounded by, encircled by) the drain access area 145. The deactivated regions 150 may be regarded as regions (sections, pockets) of the drain access area 145 where the crystalline structure (e.g., as-grown crystalline structure, wurtzite crystal structure) of the heterojunction structure 101 corresponding to the deactivated regions 150 is locally changed (e.g., modified, altered, replaced) after forming the heterojunction structure 101. Accordingly, the heterojunction structure 101 of the deactivated regions 150 include different structural configurations than the heterojunction structure 101 of the drain access area 145.

As a result, the mechanisms that induce the 2DEG at the interface of the heterojunction structure 101 (e.g., forming a sheet of fixed positive charges at the interface of the heterojunction structure, accumulating electrons at the interface to compensate the positive charges at the interface) may be weakened or prohibited in the deactivated regions 150. In other words, the effect of polarization discontinuity may be regarded as reduce or annihilated in the deactivated regions 150. As such, the deactivated regions 150 may also be referred to as inactivated regions, inert regions, isolation regions, or neutral regions. In this manner, the drain access area 145 may have a first charge carrier concentration (e.g., electron concentration of the 2DEG 165) while the deactivated regions 150 may have a second charge carrier concentration that is less than the first charge carrier concentration. In some embodiments, the deactivated regions 150 may lack the 2DEG 165, and include an intrinsic electron concentration of the GaN layer 110 (e.g., when the GaN layer 110 is undoped).

As depicted in FIG. 1, the deactivated regions 150 are aligned with the hybrid drain contact structures 135 along a direction of current flow between the source and drain contact structures 120 and 125. Moreover, the deactivated regions 150 are arranged such that the edge 156 of the footprint of the field plate 155 intersects the deactivated regions 150. As described in more details with reference to FIGS. 3A and 3B, the deactivated regions 150 are expected to locally reduce the electric field present between the field plate 155 and the drain access area 145.

FIGS. 2A through 2C are plan-view and cross-sectional schematic diagrams of a GaN device in accordance with embodiments of the present disclosure. FIG. 2A illustrates a plan-view schematic diagram of the GaN transistor 100 described with reference to FIG. 1. FIGS. 2B and 2C illustrate cross-sectional schematic diagrams of the GaN transistor 100 through imaginary lines AA and BB of FIG. 2A, respectively. Moreover, FIGS. 2A through 2C employ the same reference numbers used in FIG. 1 to denote the same or substantially similar structures. These figures are described concurrently in the following discussion.

The GaN transistor 100 includes a source contact structure (e.g., source contact structure 120b or 120c) of an array of source contact structures, a drain contact structure (e.g., drain contact structure 125b) of an array of drain contact structures, and a gate contact structure (e.g., gate contact structure 130) located between the source and drain contact structures. The GaN transistor 100 also includes a hybrid drain contact structure (e.g., hybrid drain contact structure 135a) of an array of hybrid drain contact structures. The hybrid drain contact structure is located alongside of the drain contact structure. In this manner, individual drain contact structures alternate with individual hybrid drain contact structures. A plane 275 perpendicular to a direction of current flow between the source and drain contact structures (e.g., between the source and drain contact structures 120c and 125b) (and perpendicular to the top side 116 of the GaN-based alloy layer 115) intersects the drain contact structure and the hybrid drain contact structure.

The GaN transistor 100 includes a drain access area (e.g., drain access area 145) of the heterojunction structure 101, which is located between the drain contact structure and the gate contact structure. The drain access area forms a channel (e.g., 2DEG 165 formed at the interface of the heterojunction structure 101) that is configured to couple the source contact structure to the drain contact structure when the GaN transistor 100 is ON. In other words, the drain access area includes a first layer of electrons with a first electron concentration at a surface of the GaN layer facing the GaN-based alloy layer.

The GaN transistor 100 includes a field plate (e.g., field plate 155) disposed over the source and gate contact structures. In some embodiments, the field plate is connected to the source contact structure through an interconnect 260 as depicted in FIGS. 2B and 2C. The interconnect 260 may be a contact or a via structure formed in a dielectric layer present above the heterojunction structure 101. In some embodiments, the field plate 155 is a first metal (MT1) structure. The field plate is placed such that an edge (e.g., edge 156) of the footprint of the field plate intersects the drain access area. During certain operations of the GaN transistor 100, the field plate may facilitate bifurcating electric field present between the drain access area and conductive structures above the heterojunction structure 101—e.g., the gate contact structure 130. For example, absent the field plate, the electric field may concentrate in a relatively narrow segment of the dielectric layer between the drain access area and the gate contact structure, which in turn may result in premature TDDB failure. The field plate is configured to provide an additional electrode (tied to the same potential as the source contact structure) such that a portion of the electric field may be divided (bifurcated) to the field plate.

The GaN transistor 100 also includes a deactivated region (e.g., deactivated region 150a) enclosed by the drain access area. As depicted in FIG. 2A, the inactive region is aligned with the hybrid drain contact structure along a direction of current flow between the source and drain contact structures. Moreover, the edge (e.g., edge 156) of the footprint of the field plate intersects the deactivated region.

As described herein, the heterojunction structure 101 of the deactivated region includes different structural configurations than the heterojunction structure 101 of the drain access area such that portions of the channel corresponding to the deactivated region may have a charge carrier concentration (e.g., electron concentration) that is less than that of the drain access area. As schematically depicted in FIG. 2C, the deactivated region includes a second layer 270 of electrons with a second electron concentration at the surface of the GaN layer facing the GaN-based alloy layer, where the second electron concentration is less than the first electron concentration of the drain access area (e.g., 2DEG 165). In some embodiments, the second layer 270 of electrons of the deactivated region may include an intrinsic electron concentration of the GaN layer 110.

FIGS. 3A and 3B are cross-sectional schematic diagrams of GaN devices (e.g., GaN transistor) in accordance with embodiments of the present disclosure. The GaN transistor illustrated in FIG. 3A includes aspects of the GaN transistor 100 except that deactivated regions are omitted to explain the effect of having the deactivated regions. The GaN transistor illustrated in FIG. 3B includes aspects of the GaN transistor 100 described with reference to FIGS. 1 through 2C. Both diagrams of FIGS. 3A and 3B are through the imaginary line BB of FIG. 2A. Moreover, FIGS. 3A and 3B employ the same reference numbers used in FIGS. 1 through 2A-2C to denote the same or substantially similar structures. These figures are described concurrently in the following discussion.

The GaN transistors illustrated in FIGS. 3A and 3B include another field plate (e.g., field plate 355). The field plate 355 is connected to the field plate 155 through an interconnect 360. The interconnect 360 may be a via structure formed in a dielectric layer present above the field plate 155. In some embodiments, the field plate 355 is a second metal (MT2) structure. As described herein with reference to the field plate 155 (a first field plate), the field plate 355 (a second field plate) may facilitate further bifurcating (dividing) the electric field present between the drain access area and conductive structures above the heterojunction structure 101. As with the field plate 155, the field plate 355 is placed such that an edge of the footprint of the field plate 355 intersects the drain access area (e.g., at a location closer to the drain contact structures).

Illustrated in FIGS. 3A and 3B is the charge distribution in the drain access area between the gate contact structure 130 and the hybrid drain contact structure 135a when the GaN transistors are under a high-voltage operating condition. For example, the source and gate contact structures 120b and 130 are at the ground potential (e.g., 0V), turning the GaN transistors OFF (e.g., 2DEG under the gate contact structure 130 is depleted). The substrate 105 is at the ground potential. Further, the drain contact structures and the hybrid drain contact structure 135a are connected to a high drain bias voltage (e.g., 520V). As a result of applying the high drain bias voltage, the 2DEG in the drain access area may be depleted.

As described above, electrons can be accumulated at the interface of the heterojunction structure 101—e.g., to compensate a sheet of positive fixed charges there in the absence of externally applied voltage. As a result of depleting the 2DEG under the high-voltage operating condition, the positive fixed charges may be exposed (e.g., uncompensated). Moreover, under the high drain bias voltage, the p-GaN layer 140a may inject holes (denoted as h+ in FIGS. 3A and 3B) into the drain access area, adding to the positive fixed charge, thereby locally increasing the net positive charge in the drain access area. Accordingly, the drain access area between the gate contact structure 130 and the hybrid drain contact structure 135a may have a relatively greater amount of the net positive charges—e.g., when compared to the drain access area between the gate contact structure 130 and the drain contact structure 125. In this regard, the overall charge distribution in the drain access area depicted in FIGS. 3A and 3B may be considered as a representation of net positive charge imaged (mapped) to the field plate 155 under the stress condition although specific distribution of various charges (e.g., polarization charge within the heterojunction structure 101) under the stress condition may be more sophisticated.

Referring to FIG. 3A, an electric field 380 (first electric field) is depicted as a collection of upward arrows between the drain access area (having a first amount of the net positive charge) and the field plate 155 at the ground potential. The electric field 380 may be strong enough—e.g., during the high voltage operating conditions—to degrade a TDDB lifetime of the dielectric layer present between the heterojunction structure 101 and the field plate 155.

Experimentally observed locations of the TDDB failures (e.g., localized rupture or destruction of the dielectric layer above the heterojunction structure 101) corroborate with the net charge distribution scheme described with reference to FIG. 3A. For example, the failure sites tend to be between the edge of the first field plate and spots in the drain access area, which tend to align with the locations of the hybrid drain structures. Moreover, experimental results based on the emission microscopy study support the net positive charge distribution scheme. Namely, the emission signal profile (a manifestation of the electric field strength) taken across the width of the drain access area (i.e., perpendicular to the direction of current flow between source and drain contact structures) exhibits a pattern having periodic peaks of the emission signal, in which the periodic peaks of the emission signal match with the periodic locations of the hybrid drain structures.

Referring to FIG. 3B, an electric field 381 (second electric field) is depicted as a collection of upward arrows between the drain access area (having a second amount of the net positive charge) and the field plate 155 at the ground potential. Also depicted in FIG. 3B is absence (or a less amount) of the positive charge (by omitting “+” signs) in the drain access area, which corresponds to the deactivated region 150a. As such, the second amount of the net positive charge depicted in FIG. 3B may be less than the first amount of the net positive charge depicted in FIG. 3A. When compared to the electric field 380, the electric field 381 may be reduced in view of the less amount of the net positive charge as a result of forming the deactivated region 150a. In this manner, the second electric field 381 can be reduced (the degree of reduction represented as upward arrows with broken lines) when compared to the first electric field 381.

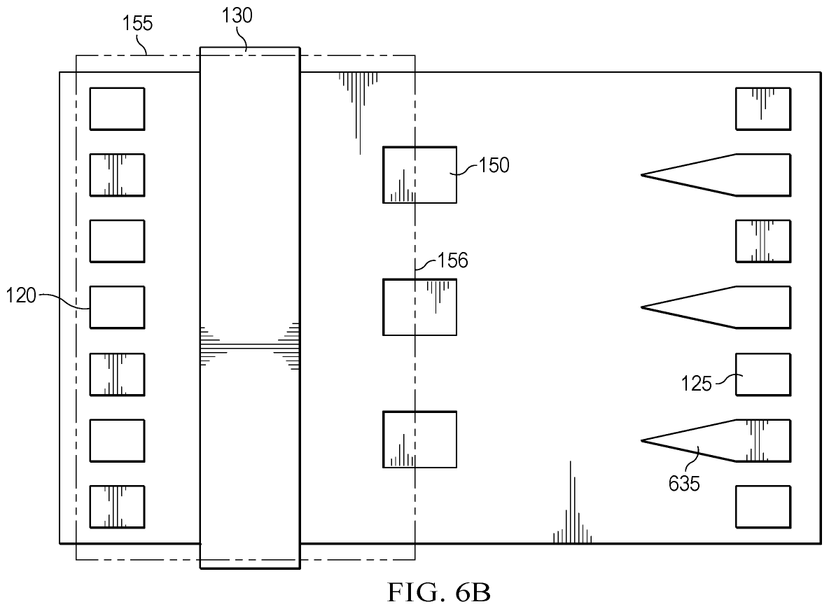

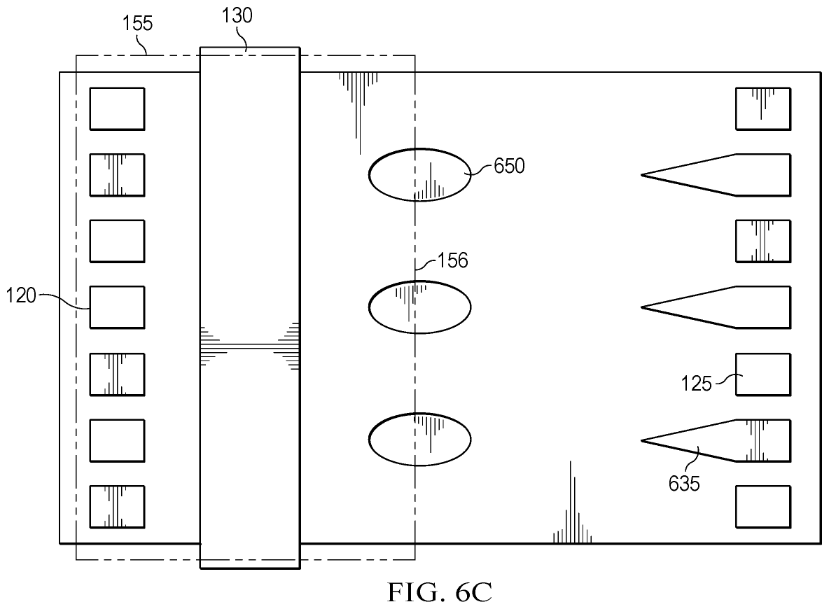

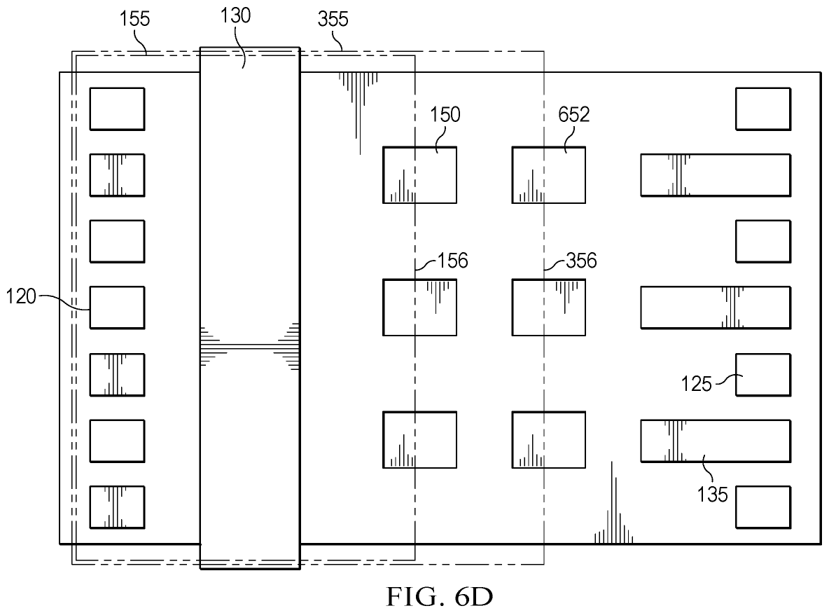

In some embodiments, additional deactivated regions may be formed (as shown in FIG. 6D) at additional locations of the heterojunction structure 101. As with the deactivated region 150a, the additional deactivated regions can be configured to reduce the electric field present between the drain access area and the field plate 355 at the ground potential. As such, an edge of a footprint of the field plate 355 may intersect the additional deactivated regions. Moreover, the additional deactivated regions may be aligned to the corresponding hybrid drain contact structures.

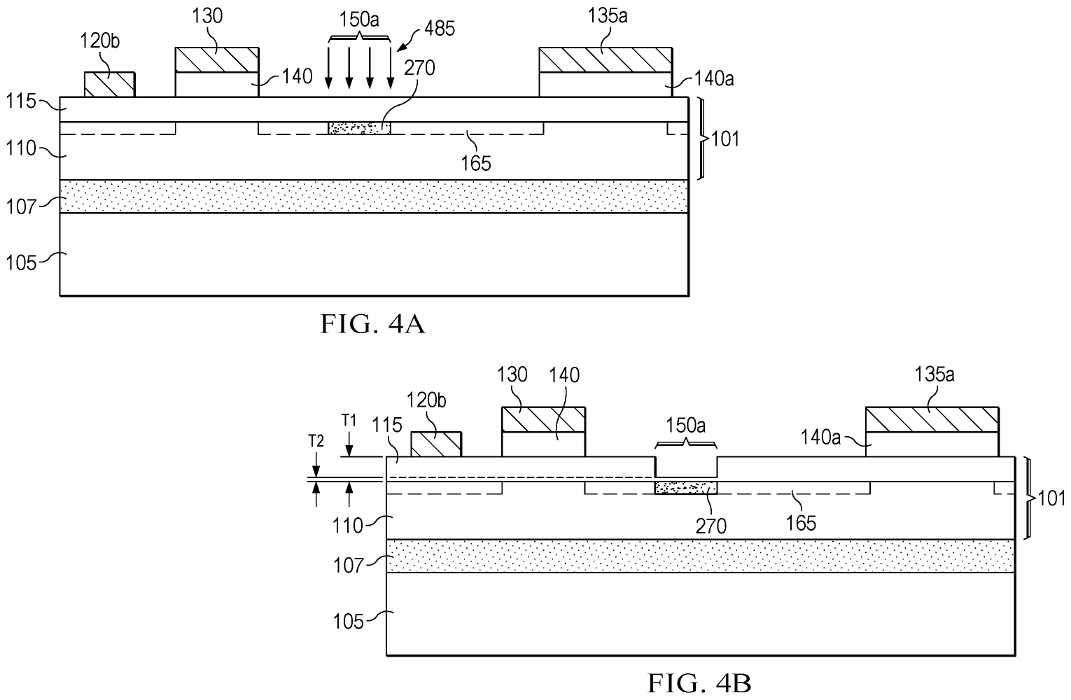

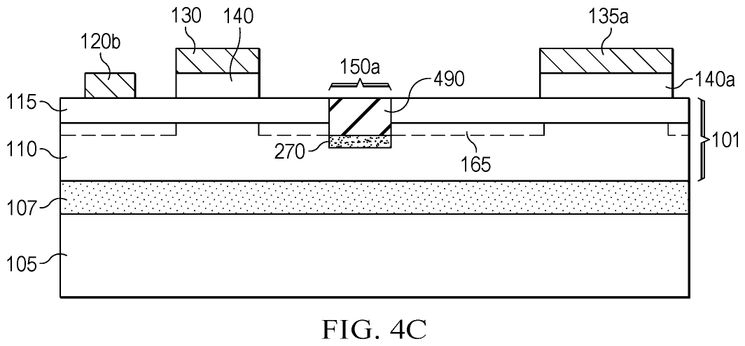

FIGS. 4A though 4C are cross-sectional schematic diagrams of GaN devices (e.g., GaN transistors) in accordance with embodiments of the present disclosure. The GaN transistors illustrated in FIGS. 4A through 4C include aspects of the GaN transistor 100 described with reference to FIGS. 1, 2A-2C, and 3B. The diagrams of FIGS. 4A through 4C are through the imaginary line BB of FIG. 2A. Moreover, FIGS. 4A through 4C employ the same reference numbers used in FIGS. 1 through 3B to denote the same or substantially similar structures. FIGS. 4A through 4C illustrate how the heterojunction structure 101 corresponding to the deactivated regions can be structurally modified—e.g., to reduce the electric field so as to mitigate the TDDB lifetime issues of the GaN transistors.

FIG. 4A illustrates that the deactivated regions 150 may be formed by selectively implanting foreign atoms (i.e., atoms different than the constituent atoms of the heterojunction structure 101) into the heterojunction structure 101. The implanted atoms, which are indicated as downward arrows 485 in FIG. 4A, may alter (e.g., destroy, perturbate, damage) the crystalline structure of the heterojunction structure 101, which is formed by the constituent atoms of the heterojunction structure 101. Moreover, the implantation process conditions (e.g., dose and energy) under which the atoms are implanted can be tailored so as to alter the crystalline structure of the heterojunction structure 101.

In some embodiments, the GaN-based alloy layer of the drain access area has a crystalline structure (e.g., as-grown crystalline structure, wurtzite crystalline structure formed by constituent atoms of the GaN-based alloy), while the GaN-based alloy layer of the deactivated region includes one or more groups of the constituent atoms that may be regarded as randomly positioned, failing to maintain the crystalline structure (or failing to form a repetitive lattice structure). In some embodiments, the GaN-based alloy layer (and at least some portion of the underlying GaN layer in some cases) of the deactivated region may become amorphous. As a result, the 2DEG formation is locally reduced (weakened), or prohibited in some cases, in the deactivated regions 150. In some embodiments, the foreign atoms include argon, vanadium, other elements suitable for altering the crystalline structure of the heterojunction structure 101.

FIG. 4B illustrates that the deactivated regions 150 may be formed by selectively reducing the thickness of the GaN-based alloy layer 115—e.g., by utilizing etching process. For example, the GaN-based alloy layer 115 may have an initial thickness T1 (e.g., as-grown thickness) in the drain access area. As a result of the etch process, the GaN-based alloy layer 115 of the deactivated regions 150 may have a final thickness T2 that is less than the initial thickness T1. In some embodiments, the final thickness T2 may be reduced to zero—i.e., the GaN-based alloy layer 115 removed completely. Effects of the polarization discontinuity is expected to be reduced when the thickness of the GaN-based alloy layer 115 is decreased. As a result, 2DEG formation is locally reduced (weakened), or prohibited in some cases, in the deactivated regions 150. In some embodiments, the recess generated by the etching process may extend through the GaN-based alloy layer 115 and terminate within the GaN layer 110—e.g., approximately 5 to 10 nm into the GaN layer 110. The term “approximately,” as used herein, may refer to ±5% to ±10% variations of the recited values in some cases. In other cases, the term “approximately” may refer to ±10% to ±20% variations of the recited values.

FIG. 4C illustrates the deactivated regions 150 may be formed by locally replacing portions of the heterojunction structure 101 corresponding to the deactivated regions 150 with one or more dielectric materials. For example, trench structures 490 can be formed in the heterojunction structure 101 corresponding to the deactivated regions 150 by removing the GaN-based alloy layer and at least a portion of the GaN layer of the deactivated region. Subsequently, the trench structures 490 can be filled with one or more dielectric materials, for example, silicon oxide, silicon nitride, silicon oxynitride, aluminum oxide, aluminum nitride, or the like. In this manner, the trench structures 490, which may resemble mesa isolation structures, can be formed such that 2DEG formation is locally prohibited in the deactivated regions 150—e.g., as a result of removing the GaN-based alloy layer.

As described herein, locally confined structural alteration of the regions (portions, pockets) of the heterojunction structure 101 corresponding to the deactivated regions 150 weakens or prohibits 2DEG formation at the interface of the heterojunction structure 101. In other words, the amount of positive fixed charges associated with the crystalline structure of the heterojunction structure 101 becomes locally reduced or eliminated such that the net positive charge imaged (mapped) to the field plate 155 under high-voltage operating conditions can be reduced. In this manner, the electric field detrimental to the reliability of the GaN transistors can be mitigated—e.g., to alleviate the TDDB lifetime issues.

FIGS. 5A through 5L are plan-view and cross-sectional schematic diagrams illustrating process steps of generating a GaN device in accordance with embodiments of the present disclosure. FIGS. 5A, 5D, 5G, and 5J are plan-view schematic diagrams associated with various process steps to fabricate the GaN transistor 100 described with reference to FIGS. 1 through 2C. FIGS. 5B/5C, 5E/5F, 5H/5I, and 5K/5L are cross-sectional schematic diagrams of the GaN transistor 100 through the imaginary lines AA and BB, respectively, at corresponding process steps depicted in FIGS. 5A, 5D, 5G, and 5J. Moreover, FIGS. 5A through 5L employ the same reference numbers used in FIGS. 1 through 3B to denote the same or substantially similar structures.

FIGS. 5A-5C illustrate that the heterojunction structure 101 including the GaN layer 110 and the GaN-based alloy layer 115 is formed over the substrate 105. The GaN-based alloy layer 115 has the top surface 116. In other words, the heterojunction structure 101 has the top surface 116. In some embodiments, the buffer layer 107 may be disposed between the substrate 105 and the heterojunction structure 101 (i.e., between the substrate 105 and the GaN layer 110). In some embodiments, an epitaxial process may be utilized to form the heterojunction structure 101 over the substrate 105. When the heterojunction structure 101 is formed, the 2DEG 165 is formed at the interface between the GaN layer 110 and the GaN-based alloy layer 115—e.g., at the surface of the GaN layer 110 in contact with the GaN-based alloy layer 115.

FIGS. 5D-5F illustrate that the p-GaN layer 140 is formed on the GaN-based alloy layer 115, and subsequently patterned to remove unnecessary portions of the p-GaN layer 140. In some embodiments, the p-GaN layer 140 is grown on the GaN-based alloy layer 115 as part of the epitaxial process that forms the heterojunction structure 101. In some embodiments, although not shown explicitly, a dielectric layer (e.g., silicon nitride layer) may be formed on the p-GaN layer 140 to protect the surface of the epitaxially grown layers—e.g., during subsequent process steps. As a result of forming the p-GaN layer 140 (e.g., when the epitaxial process is complete), the 2DEG 165 may have been depleted at the interface of the heterojunction structure 101 as described above. After the unnecessary portions of the p-GaN layer 140 are removed, however, the 2DEG 165 is restored where the p-GaN layer 140 is absent. In some embodiments, although not shown explicitly, another dielectric layer (e.g., silicon nitride layer) may be formed to protect the exposed surface of the GaN-based alloy layer 115—e.g., during subsequent process steps.

FIGS. 5G-5I illustrate that the deactivated regions 150 are formed at the selected locations of the heterojunction structure 101. As described with reference to FIGS. 4A through 4C, various process steps can be carried out so as to locally modify the structural configuration of the heterojunction structure 101 in the deactivated regions 150. As a result, the deactivated regions 150 may include the second layer 270 of electrons with a second electron concentration at the surface of the GaN layer, which is less than the first electron concentration of the drain access area (e.g., 2DEG 165). As described herein, each of the deactivated regions 150 is aligned with corresponding hybrid drain contact structure 135 (to be formed on the p-GaN layer 140a). Moreover, the edge 156 of the footprint of the field plate 155 intersects the deactivated regions 150 as depicted in FIG. 2C. In some embodiments, additional deactivated regions (not shown in FIG. 5I) may be formed at additional locations of the heterojunction structure 101. As described in more detail with reference to FIG. 6D, an edge of a footprint of the field plate 355 intersects the additional deactivated regions. Moreover, the additional deactivated regions are aligned to the corresponding hybrid drain contact structures.

FIGS. 5J-5L illustrate that the source contact structures 120, the drain contact structures 125, the gate contact structure 130, and the hybrid drain contact structure 135 are formed. In some embodiments, the dielectric layers over the GaN-based alloy layer 115 and over the p-GaN layer 140 may be removed to facilitate forming the ohmic contact between the contact structures and corresponding epitaxial layers. In some embodiments, annealing steps may be carried out after forming the contact structures. As a result of the annealing steps, that electrons can conduct through the GaN-based alloy layer 115 between the 2DEG 165 and the source and drain contact structures 120 and 125, respectively. Subsequently, various dielectric layers (e.g., silicon oxide layers, silicon nitride layers) may be deposited over the heterojunction structure 101 and the contact structures to form various interconnects and conductive layers—e.g., contact/via 260/360, field plates 155 and 355.

FIGS. 6A through 6D are plan-view schematic diagrams of GaN devices (e.g., GaN transistors) in accordance with embodiments of the present disclosure. The GaN transistors illustrated in FIGS. 6A through 6D include aspects of the GaN transistor 100 described with reference to FIGS. 1, 2A-2C, and 3B. Moreover, FIGS. 6A through 6D employ the same reference numbers used in FIGS. 1, 2A-2C, and 3B to denote the same or substantially similar structures. As depicted in FIGS. 6A through 6D, the GaN transistor 100 may be modified to include various structures different than those of the GaN transistor 100.

For example, the GaN transistor depicted in FIG. 6A includes a single source contact structure 620 in lieu of the array of source contact structures 120. Another example GaN transistor depicted in FIG. 6B includes hybrid drain contact structures 635 (and corresponding p-GaN layers 140) that include pointed ends (or round ends after patterning process steps) toward the gate contact structure 130 in lieu of the hybrid drain contact structures 135 of rectangular shapes. Yet another example GaN transistor depicted in FIG. 6C includes deactivated regions 650 with an elliptical (or oval) shape that may facilitate reducing the impact of having deactivated regions in the drain access area. For example, the dynamic R_{DS_ON} may increase as a result of sacrificing portions of the drain access area when the deactivated regions are formed. As such, the shape of deactivated regions (e.g., deactivated regions 150 or 650) may have any shape suitable for reducing the increase in the dynamic R_{DS_ON}, for example, a triangular shape, a trapezoidal shape, among others.

Yet another example GaN transistor depicted in FIG. 6D includes a second field plate (e.g., field plate 355) and additional deactivated regions 652. As described herein, the additional deactivated regions 652 may reduce the electric field present between the drain access area and the field plate 355 during certain high voltage operating conditions—e.g., the source and gate contact structures as well as the first field plate 155 and the second field plate 355 being at the ground potential (e.g., 0V) and the drain and hybrid drain contact structures being connected to a high drain bias voltage (e.g., 520V). As shown in FIG. 6D, an edge (e.g., edge 356) of a footprint of the field plate 355 intersects the additional deactivated regions 652. Moreover, the additional deactivated regions 652 are aligned to the corresponding hybrid drain contact structures 135.

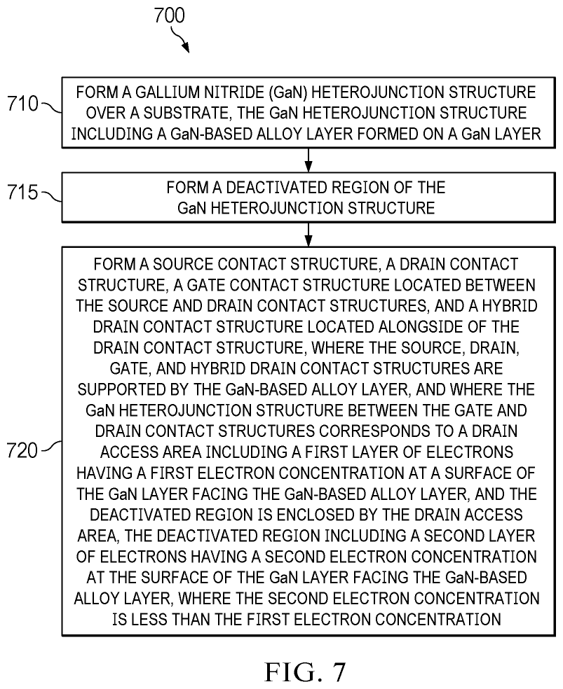

FIG. 7 is a flowchart 700 illustrating methods of generating GaN devices in accordance with aspects of the present disclosure. The flowchart 700 includes aspects of methods described with reference to FIGS. 4A-4C and 5A-5L. The method includes forming a gallium nitride (GaN) heterojunction structure over a substrate, the GaN heterojunction structure including a GaN-based alloy layer formed on a GaN layer (box 710). The method further includes forming a deactivated region of the GaN heterojunction structure (box 715). The method further includes forming a source contact structure, a drain contact structure, a gate contact structure located between the source and drain contact structures, and a hybrid drain contact structure located alongside of the drain contact structure, where the source, drain, gate, and hybrid drain contact structures are supported by the GaN-based alloy layer, and where the GaN heterojunction structure between the gate and drain contact structures corresponds to a drain access area including a first layer of electrons having a first electron concentration at a surface of the GaN layer facing the GaN-based alloy layer, and the deactivated region is enclosed by the drain access area, the deactivated region including a second layer of electrons having a second electron concentration at the surface of the GaN layer facing the GaN-based alloy layer, where the second electron concentration is less than the first electron concentration (box 720).

In some embodiments, the method further includes forming first and second p-doped GaN (p-GaN) layers on a top side of the GaN-based alloy layer facing away the substrate, where the gate and hybrid drain contact structures are supported by the first and second p-GaN layers, respectively. In some embodiments, forming the deactivated region includes implanting the deactivated region with atoms different than constituent atoms of the GaN heterojunction structure, wherein the GaN-based alloy layer of the deactivated region includes one or more groups of the constituent atoms that are randomly positioned as a result of implanting the atoms. In some embodiments, the implanted atoms include argon, vanadium, or both.

In some embodiments, forming the deactivated region includes removing at least a portion of the GaN-based alloy layer of the deactivated region such that the GaN-based alloy layer of the drain access area has a first thickness, and the GaN-based alloy layer of the deactivated region has a second thickness that is less than the first thickness. In some embodiments, forming the deactivated region includes removing the GaN-based alloy layer and at least a portion of the GaN layer of the deactivated region to a trench structure, and filling the trench structure with one or more dielectric materials.

In some embodiments, the deactivated region is aligned with the hybrid drain contact structure along a direction of current flow between the source and drain contact structures. In some embodiments, the method further includes forming a field plate over the source and gate contact structures, wherein an edge of a footprint of the field plate intersects the deactivated region. In some embodiments, a plane perpendicular to a direction of current flow between the source and drain contact structures intersects the drain contact structure and the hybrid drain contact structure.

While various embodiments of the present disclosure have been described above, it is to be understood that they have been presented by way of example and not limitation. Numerous changes to the disclosed embodiments can be made in accordance with the disclosure herein without departing from the spirit or scope of the present disclosure. In addition, while in the illustrated embodiments various features or components have been shown as having particular arrangements or configurations, other arrangements and configurations are possible. Moreover, aspects of the present technology described in the context of example embodiments may be combined or eliminated in other embodiments. Thus, the breadth and scope of the present disclosure is not limited by any of the above described embodiments.

What is claimed is:

1. A transistor, comprising:
a gallium nitride (GaN) heterojunction structure over a substrate, the GaN heterojunction structure including a GaN-based alloy layer formed on a GaN layer;
a source contact structure, a drain contact structure, and a gate contact structure located between the source and drain contact structures, wherein the source, drain, and gate contact structures are supported by the GaN-based alloy layer; and
a hybrid drain contact structure located alongside of the drain contact structure, wherein the hybrid drain contact structure is supported by the GaN-based alloy layer, and wherein—
the GaN heterojunction structure includes:
a drain access area between the gate and drain contact structures, the drain access area having a first layer of electrons with a first electron concentration at a surface of the GaN layer facing the GaN-based alloy layer; and
a deactivated region enclosed by the drain access area, the deactivated region having a second layer of electrons with a second electron concentration at the surface of the GaN layer facing the GaN-based alloy layer, wherein the second electron concentration is less than the first electron concentration.

2. The transistor of claim 1, wherein the deactivated region is aligned with the hybrid drain contact structure along a direction of current flow between the source and drain contact structures.

3. The transistor of claim 1, wherein a plane perpendicular to a direction of current flow between the source and drain contact structures intersects the drain contact structure and the hybrid drain contact structure.

4. The transistor of claim 1, wherein the second electron concentration corresponds to an intrinsic electron concentration of the GaN layer.

5. The transistor of claim 1, wherein:
the GaN-based alloy layer of the drain access area has a crystalline structure formed by constituent atoms of the GaN-based alloy; and
the GaN-based alloy layer of the deactivated region includes one or more groups of the constituent atoms that are randomly positioned.

6. The transistor of claim 5, wherein the GaN-based alloy layer of the deactivated region comprises atoms different than the constituent atoms, the atoms including argon, vanadium, or both.

7. The transistor of claim 1, wherein:
the GaN-based alloy layer of the drain access area has a first thickness; and
the GaN-based alloy layer of the deactivated region has a second thickness that is less than the first thickness.

8. The transistor of claim 1, wherein the GaN-based alloy layer of the GaN heterojunction structure of the deactivated region is removed.

9. The transistor of claim 1, wherein a trench structure filled with one or more dielectric materials replaces a part of the GaN heterojunction structure of the deactivated region, the part of the GaN heterojunction structure including the GaN-based alloy layer and a portion of the GaN layer.

10. The transistor of claim 1, further comprising:
a field plate over the source and gate contact structures, wherein an edge of a footprint of the field plate intersects the deactivated region.

11. The transistor of claim 10, wherein the field plate is connected to the source contact structure.

12. The transistor of claim 10, wherein the deactivated region is a first deactivated region and the field plate is a first field plate, the transistor further comprising:
a second deactivated region located between the first deactivated region and the hybrid drain contact structure, wherein the second deactivated region is aligned with the hybrid drain contact structure along a direction of current flow between the source and drain contact structures; and
a second field plate over the first field plate, wherein an edge of a footprint of the second field plate intersects the second deactivated region.

13. The transistor of claim 12, wherein the second deactivated region is enclosed by the drain access area, the second deactivated region having a third layer of electrons with the second electron concentration at the surface of the GaN layer facing the GaN-based alloy layer.

14. The transistor of claim 12, wherein the second field plate is connected to the source contact structure.

15. The transistor of claim 1, further comprising:
a p-doped GaN layer positioned on a top side of the GaN-based alloy layer facing away the substrate, wherein the gate contact structure is positioned on the p-doped GaN layer.

16. The transistor of claim 1, further comprising:
a p-doped GaN layer positioned on a top side of the GaN-based alloy layer facing away the substrate, wherein the hybrid drain contact structure is positioned on the p-doped GaN layer.

17. The transistor of claim 1, further comprising:
an array of drain contact structures including the drain contact structure;
an array of hybrid drain contact structures including the hybrid drain contact structure, wherein:
individual drain contact structures alternate with individual hybrid drain contact structures; and
a plane perpendicular to a direction of current flow between the source and drain contact structures intersects individual drain contact structures and individual hybrid drain contact structures.

18. The transistor of claim 17, further comprising:
an array of deactivated regions including the deactivated region, wherein individual deactivated regions are enclosed by the drain access area and aligned with corresponding hybrid drain contact structures along the direction of current flow.

19. The transistor of claim 18, further comprising:
a field plate over the source and gate contact structures, wherein an edge of a footprint of the field plate intersects individual deactivated regions.

20. The transistor of claim 1, further comprising:
a silicon nitride layer disposed on the GaN-based alloy layer.

21. A method, comprising:
forming a gallium nitride (GaN) heterojunction structure over a substrate, the GaN heterojunction structure including a GaN-based alloy layer formed on a GaN layer;
forming a deactivated region of the GaN heterojunction structure; and
forming a source contact structure, a drain contact structure, a gate contact structure located between the source and drain contact structures, and a hybrid drain contact structure located alongside of the drain contact structure, wherein the source, drain, gate, and hybrid drain contact structures are supported by the GaN-based alloy layer, and wherein—
the GaN heterojunction structure between the gate and drain contact structures corresponds to a drain access area including a first layer of electrons having a first electron concentration at a surface of the GaN layer facing the GaN-based alloy layer; and
the deactivated region is enclosed by the drain access area, the deactivated region including a second layer of electrons having a second electron concentration at the surface of the GaN layer facing the GaN-based alloy layer, wherein the second electron concentration is less than the first electron concentration.

22. The method of claim 21, further comprising:
forming first and second p-doped GaN (p-GaN) layers on a top side of the GaN-based alloy layer facing away the substrate, wherein the gate and hybrid drain contact structures are supported by the first and second p-GaN layers, respectively.

23. The method of claim 21, wherein forming the deactivated region includes:
implanting the deactivated region with atoms different than constituent atoms of the GaN heterojunction structure, wherein the GaN-based alloy layer of the deactivated region includes one or more groups of the constituent atoms that are randomly positioned as a result of implanting the atoms.

24. The method of claim 23, wherein the atoms different than the constituent atoms include argon, vanadium, or both.

25. The method of claim 21, wherein forming the deactivated region includes:
removing at least a portion of the GaN-based alloy layer of the deactivated region such that the GaN-based alloy layer of the drain access area has a first thickness, and the GaN-based alloy layer of the deactivated region has a second thickness that is less than the first thickness.

26. The method of claim 21, wherein forming the deactivated region includes:
removing the GaN-based alloy layer and at least a portion of the GaN layer of the deactivated region to a trench structure; and
filling the trench structure with one or more dielectric materials.

27. The method of claim 21, wherein the deactivated region is aligned with the hybrid drain contact structure along a direction of current flow between the source and drain contact structures.

28. The method of claim 21, further comprising:
forming a field plate over the source and gate contact structures, wherein an edge of a footprint of the field plate intersects the deactivated region.

29. The method of claim 21, wherein a plane perpendicular to a direction of current flow between the source and drain contact structures intersects the drain contact structure and the hybrid drain contact structure.

30. A high electron mobility transistor (HEMT), comprising:
a gallium nitride (GaN) heterojunction structure over a substrate, the GaN heterojunction structure including a GaN-based alloy layer formed on a GaN layer;
a source contact structure, a plurality of drain contact structures, and a gate contact structure located between the source contact structure and the plurality of drain contact structures, wherein the source, drain, and the gate contact structures are supported by the GaN-based alloy layer; and
a plurality of hybrid drain contact structures supported by the GaN-based alloy layer, wherein individual drain contact structures alternate with individual hybrid drain contact structures, and wherein—
the GaN heterojunction structure includes:
a drain access area between the gate and the plurality of drain contact structures, the drain access area including a first layer of electrons having a first electron concentration at a surface of the GaN layer facing the GaN-based alloy layer; and
a plurality of deactivated regions with each of the deactivated regions enclosed by the drain access area and including a second layer of electrons having a second electron concentration at the surface of the GaN layer facing the GaN-based alloy layer, wherein the second electron concentration is less than the first electron concentration.

31. The HEMT of claim 30, wherein individual deactivated regions are aligned with corresponding hybrid drain contact structures along a direction of current flow between the source contact structure and the plurality of drain contact structures.

32. The HEMT of claim 30, wherein:
the GaN-based alloy layer of the drain access area has a crystalline structure formed by constituent atoms of the GaN-based alloy; and
the GaN-based alloy layer of each one of the deactivated regions includes one or more groups of the constituent atoms that are randomly positioned.

33. The HEMT of claim 30, wherein:
the GaN-based alloy layer of the drain access area has a first thickness; and
the GaN-based alloy layer of each one of the deactivated regions has a second thickness that is less than the first thickness.

34. The HEMT of claim 30, wherein each one of the deactivated regions includes a trench structure filled with one or more dielectric materials that replaces a part of the GaN heterojunction structure of the deactivated region, the part of the GaN heterojunction structure including the GaN-based alloy layer and a portion of the GaN layer.

35. The HEMT of claim 30, further comprising:
a field plate over the source contact structure and the gate contact structure, wherein an edge of a footprint of the field plate intersects the plurality of deactivated regions.

36. The HEMT of claim 35, wherein the plurality of deactivated regions is a plurality of first deactivated regions, and the field plate is the first field plate, the HEMT further comprising:
a plurality of second deactivated regions located between the plurality of first deactivated regions and the plurality of hybrid drain contact structures, wherein individual second deactivated regions of the plurality are aligned with corresponding hybrid drain contact structures along a direction of current flow between the source contact structure and the plurality of drain contact structures; and
a second field plate over the first field plate, wherein an edge of a footprint of the second field plate intersects the plurality of second deactivated regions.

37. The transistor of claim 36, wherein each of the second deactivated regions is enclosed by the drain access area, and includes a third layer of electrons with the second electron concentration at the surface of the GaN layer facing the GaN-based alloy layer.

38. The transistor of claim 36, wherein the second field plate is connected to the source contact structure.

39. The HEMT of claim 30, wherein a plane perpendicular to a direction of current flow between the source contact structure and the plurality of drain contact structures intersects the plurality of drain contact structures and the plurality of hybrid drain contact structures.

40. The HEMT of claim 30, further comprising:
a first p-doped GaN layer positioned on a top side of the GaN-based alloy layer facing away the substrate, wherein the gate contact structure is positioned on the first p-doped GaN layer; and
a plurality of second p-doped GaN layers positioned on the top side of the GaN-based alloy layer, wherein each hybrid drain contact structure of the plurality is positioned on a corresponding p-doped GaN layer of the plurality.
